(19) United States
(12) Patent Application Publication
(10) Pub. No.: US 2026/0238216 A1
(43) Pub. Date: Aug. 13, 2026

(54) ADC WITH NOISE-SHAPING SAR AND DIGITIZATION OF QUANTIZATION ERROR

(71) Applicant: Taiwan Semiconductor Manufacturing Company, Ltd., Hsinchu (TW)

(72) Inventor: Martin Kinyua, Cedar Park, TX (US)

(21) Appl. No.: 19/049,490

(22) Filed: Feb. 10, 2025

(51) Int. Cl. H03M 1/06

(52) U.S. Cl. CPC H03M 1/06

(57) ABSTRACT

An ADC device includes a first stage that has an input that receives an analog signal and an output that transmits a first digital signal based on the analog signal. The first stage includes a SAR that receives the analog signal and performs successive approximations of the analog signal to provide the first digital signal. The SAR includes a passive switched-capacitor integrator that filters off low frequency white noise and integrates a residual signal that is based on comparisons controlled by the successive approximations of the analog signal to the analog signal to generate a filtered first stage quantization error. A second stage receives and converts the filtered first stage quantization error to a second digital signal, and the digital filter combines the first digital signal and the second digital signal to provide a combined digital signal.

### BACKGROUND

Analog-to-digital converters (ADCs) are used in a variety of applications to convert an analog input signal into a digital output signal. Basically, the digital output signal is a binary number that is proportional to the analog input signal. A continuous analog input signal is periodically sampled, and each sample is converted into a discrete digital output signal. Converting a continuous analog input signal into a digital output signal requires quantization of the analog input signal, which introduces quantization error.

ADC architectures include pipelined, flash, Delta-Sigma, integrating (sloping), and successive approximation register (SAR) architectures. Pros and cons are associated with each ADC architecture. For example, Delta-Sigma ADCs can achieve relatively high resolution, such as 16 bits or higher, but bandwidth may be limited, and SAR ADCs can operate with relatively low power consumption, but may have limited resolution. In some ADC architectures it is difficult to attain a sufficiently high signal-to-noise ratio (SNR) and conversion bandwidth.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. In addition, the drawings are illustrative as examples of embodiments of the disclosure and are not intended to be limiting.

FIG. 1 is a diagram schematically illustrating a multi-stage ADC device, in accordance with some embodiments.

FIG. 2 is a diagram schematically illustrating a first stage, in accordance with some embodiments.

FIG. 3 is a diagram schematically illustrating an example of a passive switched-capacitor integrator, in accordance with some embodiments.

FIG. 4 is a diagram schematically illustrating a second stage, in accordance with some embodiments.

FIG. 5 is a diagram schematically illustrating a VTC, in accordance with some embodiments.

FIG. 6 is a diagram schematically illustrating a TDC, in accordance with some embodiments.

FIG. 7 is a diagram schematically illustrating a digital filter, in accordance with some embodiments.

FIG. 8 is a diagram illustrating Fast Fourier Transform (FFT) spectrums of ADC devices, in accordance with some embodiments.

FIG. 9 is a diagram schematically illustrating a noise-shaping SAR that is part of a first stage of an ADC device, in accordance with some embodiments.

FIG. 10 is a diagram schematically illustrating the noise-shaping SAR with the passive switched-capacitor integrator having 6 capacitors, in accordance with some embodiments.

FIG. 11 is a timing diagram illustrating the operation of the noise-shaping SAR with the passive switched-capacitor integrator, in accordance with some embodiments.

FIG. 12 is a diagram schematically illustrating a second stage, in accordance with some embodiments.

FIG. 13 is a diagram illustrating a method of converting an analog signal to a digital signal in an ADC device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

SAR ADCs are often used in applications such as sensors, data acquisition systems, and battery-powered devices. A SAR ADC makes a series of comparisons and approximations to determine a digital output signal that is proportional to and correlates to an analog input signal. The SAR ADC uses a binary search algorithm to obtain the digital output signal that correlates to the analog input signal. In some embodiments, the analog input signal is sampled and held, and the SAR ADC sets the most significant bit (MSB) of the digital output signal to 1 with the rest of the bits set to 0. A digital-to-analog converter (DAC) generates an analog output voltage based on the digital output signal. A comparator compares the DAC analog output voltage to the sampled analog input voltage and outputs a digital high or low signal depending on whether the sampled analog input voltage is higher or lower than the DAC analog output voltage. The comparator output determines whether the bit is set to 1 or 0. Next, the next most significant bit, such as MSB-1, is set to 1 and the DAC analog output voltage is compared to the sampled analog input signal to determine whether this bit is set to 1 or 0. The process continues for the remaining bits, down to the least significant bit (LSB), to obtain the digital output signal that correlates to the sampled analog input signal. Also, the DAC analog output voltage is subtracted from the sampled analog input signal to obtain a residual voltage, also referred to herein as a residue voltage, that is a quantization error.

Often, ADCs include analog high-performance circuits, such as high gain operational amplifiers, that consume a lot of power, which make it challenging to implement the SAR ADCs in advanced, deeply scaled (nanoscale) process technologies that have reduced power supply voltages.

Disclosed embodiments provide a multi-stage ADC that includes a noise-shaping SAR and digitization of the quantization error. The ADC device includes a first stage, a second stage, and a digital filter. The first stage includes the noise-shaping SAR that receives one or more analog input signals and performs successive approximations of the analog input signals to provide a first digital output signal. The SAR includes a passive switched-capacitor integrator that acts as a loop filter to filter off low frequency white noise. The passive switched-capacitor integrator integrates residual signals, also referred to herein as residue signals, that are based on comparisons of the successive approximation of the analog input signal to the analog input signal and to generate a first stage quantization error. The second stage receives the first stage quantization error and converts the first stage quantization error to a second digital output signal. The digital filter combines the first digital output signal and the second digital output signal to provide a combined final digital output signal. In some embodiments, the second stage digitizes the first stage quantization error in the time domain and outputs the second digital output signal.

Disclosed embodiments further provide an ADC device that includes a first stage that includes a SAR that performs successive approximations of an analog input signal to provide a first digital output signal. The SAR includes a passive switched-capacitor integrator that integrates residue signals based on the successive approximation of the analog signal to provide a first stage quantization error. The passive switched-capacitor integrator includes a first sampling capacitor configured to sample a first residue signal during a first set of signals and provide a first sample of the first residue signal to a first integrator capacitor during a second set of signals that is different than the first set of signals and alternates with the first set of signals, a second sampling capacitor configured to sample the first residue signal during the second set of signals and provide a second sample of the first residue signal to the first integrator capacitor during the first set of signals, a third sampling capacitor configured to sample a second residue signal during the first set of signals and provide a first sample of the second residue signal to a second integrator capacitor during the second set of signals, and a fourth sampling capacitor configured to sample the second residue signal during the second set of signals and provide a second sample of the second residue signal to the second integrator capacitor during the first set of signals.

Further disclosed embodiments include a method of operating an ADC device. The method includes: performing, by a SAR, successive approximations of a first analog signal and a second analog signal; generating, by the SAR, a first digital output signal based on the successive approximations of the first analog signal and the second analog signal; integrating, by a passive switched-capacitor integrator, a first residue signal that is based on the successive approximations of the first analog signal; integrating, by the passive switched-capacitor integrator, a second residue signal that is based on the successive approximations of the second analog signal; and generating a first stage quantization error based on the integrating of the first residual signal and the second residual signal.

The disclosed embodiments provide scalability benefits in deep nanoscale processes, such as advanced FinFET technologies. The disclosed embodiments can be implemented in low power supply voltage applications, such as where the power supply voltage is at or below 1.0-volt (V), thereby taking advantage of advanced complementary metal-oxide semiconductor (CMOS) process technologies. Also, in some embodiments, the low power supply voltage applications refer to core power supply voltages used in advanced digital processes, which may be between 0.75V to 0.96V for 5 nanometer (nm) or 3 nm technologies. In addition, the disclosed embodiments can be used in analog circuits without resorting to input/output (IO) transistor devices that have a higher voltage rating.

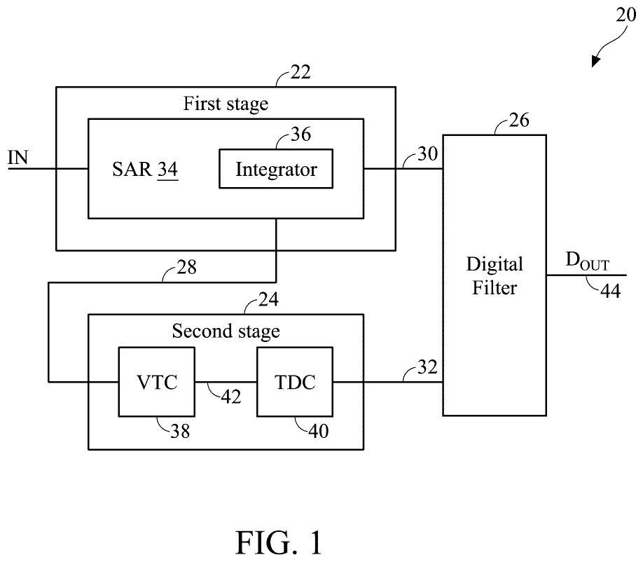

FIG. 1 is a diagram schematically illustrating a multi-stage ADC device 20, in accordance with some embodiments. The ADC device 20 performs high-pass frequency noise shaping and digitization of quantization errors. The ADC device 20 is an electronic device. In some embodiments, the ADC device 20 includes one or more semiconductor devices. In some embodiments, the ADC device 20 includes one or more integrated circuit devices.

The ADC device 20 includes a first stage 22, a second stage 24, and a digital filter 26. The first stage 22 is electrically connected to the second stage 24 by a first conductive path 28 and to the digital filter 26 by a second conductive path 30. The second stage 24 is electrically connected to the digital filter 26 by a third conductive path 32.

The first stage 22 includes a noise-shaping SAR 34 that includes a passive switched-capacitor integrator 36. The noise-shaping SAR 34 is electrically connected to the second stage 24 by the first conductive path 28 and to the digital filter 26 by the second conductive path 30. The first stage 22 includes an input IN that receives analog input signals. The noise-shaping SAR 34 performs successive approximations of the analog input signals to generate, on the second conductive path 30, first digital output signals that correspond to the analog input signals.

The passive switched-capacitor integrator 36 functions as a high-pass loop filter to filter off low frequency white noise during operation of the noise-shaping SAR 34. The passive switched-capacitor integrator 36 integrates residual signals that are based on comparisons of the analog signals from the noise-shaping SAR to the analog input signals from the input IN. Based on the residual signals, the passive switched-capacitor integrator 36 generate a first stage quantization error that is transmitted on the first conductive path 28. In some embodiments, the passive switched-capacitor integrator 36 includes multiple sampling capacitors that alternatively sample a residual signal and integrate the sampled residual signal onto an integrator capacitor, such that throughput, i.e., the sample rate, of the ADC device 20 is not reduced.

The second stage 24 receives the first stage quantization error on the first conductive path 28 and converts the first stage quantization error to a second digital output signal that is transmitted on the third conductive path 32 to the digital filter 26. The second stage 24 digitizes the first stage quantization error in the time domain and outputs the second digital output signal on the third conductive path 32.

The second stage 24 includes a voltage-to-time converter (VTC) 38 that is electrically connected to a time-to-digital converter (TDC) 40 by a fourth conductive path 42. The VTC 38 receives the first stage quantization error and converts it from a voltage into a corresponding time. The TDC 40 converts the time into the second digital output signal. Thus, the first stage quantization error is passively connected or coupled to the VTC 38 of the second stage 24 without the need for an active amplifier circuit. In some embodiments, the VTC 38 includes a zero-crossing detector (ZCD) that receives the first stage quantization error and converts the voltage into the corresponding time.

The digital filter 26 receives the first digital output signal and the second digital output signal and, in the digital domain, the digital filter combines the first digital output signal and the second digital output signal to provide a final combined digital output signal at the output D_{OUT} 44 of the digital filter 26.

The ADC device 20 includes a noise-shaping SAR 34 in the first stage 22 and a time domain quantizer in the second stage 24. Advantages of the ADC device 20 include that the noise-shaping SAR 34 not only suppresses the first stage quantization error but also suppresses the comparator noise of the noise-shaping SAR 34, which may otherwise contribute significantly to overall noise and power consumption. Also, when combined with oversampling, noise-shaping leads to highly reduced in-band quantization and comparator noise, which increases the signal-to-noise (SNR) ratio, and similarly, with oversampling, sampled in-band thermal noise, referred to as kT/C noise, on the capacitive digital-to-analog converter (CDAC) of the noise-shaping SAR 34 is scaled down. In addition, the passive switched-capacitor integrator 36 uses only passive components without the need for an active amplifier, such that no active power is consumed, which leads to power savings. Thus, the ADC device 20 can be used in deep nanoscale technologies at low power supply voltages. Where, in this context, low power supply voltages refer to low core power supply voltages used in advanced digital process technologies, such as between 0.75V to 0.96V for 5 nm or 3 nm technologies. Also, in some embodiments, the noise and non-linearity of the second stage 24 is high-pass filtered by the noise shaping function, which increases the signal-to-noise and distortion ratio (SNDR).

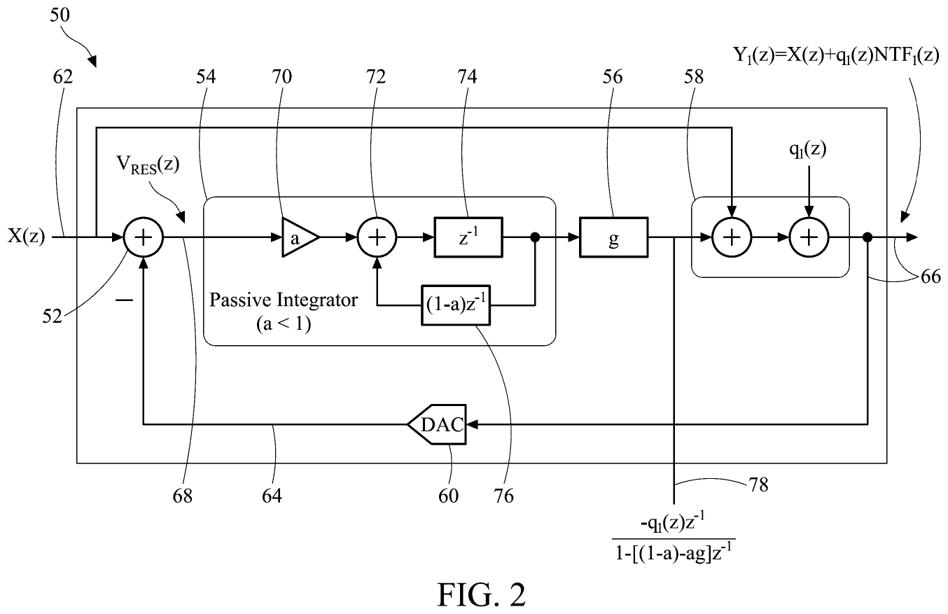

FIG. 2 is a diagram schematically illustrating a first stage 50, in accordance with some embodiments. The first stage 50 includes a noise-shaping SAR that includes a passive switched-capacitor integrator. In some embodiments, FIG. 2 is a signal flow diagram of the first stage 50 in the z-transform domain. In some embodiments, FIG. 2 is a functional diagram of the noise-shaping SAR 34 (shown in FIG. 1). In some embodiments, the first stage 50 is like the first stage 22 (shown in FIG. 1).

The first stage 50 includes a first adder 52, a passive switched-capacitor integrator 54, a first gain stage 56, a comparator 58, and a digital-to-analog converter (DAC) 60. The first stage 50 has an input 62 that receives an analog input signal X(z) that is sampled and held. The sampled analog input signal is received at a positive input of the first adder 52 and at a positive input of the comparator 58. The first adder 52 compares the sampled analog input signal to an analog output signal at an output 64 of the DAC 60, which is received at a negative input of the first adder 52. The DAC 60 receives a digital output signal on an output 66 of the first stage 50 and converts the digital output signal to the analog output signal of the DAC 60. The analog output signal of the DAC 60 approximates the sampled analog input signal. The difference between the sampled analog input signal and the analog output signal of the DAC 60 is a residue signal V_{RES}(z) at the output 68 of the first adder 52. The residue signal V_{RES}(z) is received and integrated by the passive switched-capacitor integrator 54.

The passive switched-capacitor integrator 54 includes a second gain stage 70, a second adder 72, a delay 74, and a feedback signal 76. The second gain stage 70 receives the residue signal V_{RES}(z) and applies a gain factor of “a” that is less than 1. The result is received by the second adder 72 that also receives the feedback signal 76 of (1-a)z⁻¹ from a previous summation of the second adder 72. The second adder sums the result from the second gain stage 70 and the feedback signal 76 to provide a summation result that is delayed a clock period delay in the z-transform domain Z⁻¹ by the delay 74. The first gain stage 56 receives the delayed summation result from the delay 74 and has a quantization error gain factor of “g” that is applied to the delayed summation result to provide a first stage quantization error on conductive path 78 to the second stage, such as the second stage 24 (shown in FIG. 1).

The comparator 58 sums the first stage quantization error and the sampled analog input signal, which is fed forward, with the quantization error q₁(z) introduced by the comparator 58 to generate a first output signal Y₁(z) of the first stage 50. The digital output signal of the first stage 50 is fed back to the DAC 60, which transmits the analog output signal of the DAC 60 to the first adder 52 and the process is repeated. The first output signal Y₁(z) of the first stage 50 is:

$${Y}_{1} ( z ) = X ( z ) + {q}_{1} ( z ) {NTF}_{1} ( z ) ,$$

where NTF₁ is the noise transfer function of the first stage 50, and the first stage quantization error, including the quantization error q₁(z) introduced by the comparator 58, is:

$$\frac{- q 1 ( z ) z - 1}{1 - [ ( 1 - a ) - ag ] {z}^{- 1}} .$$

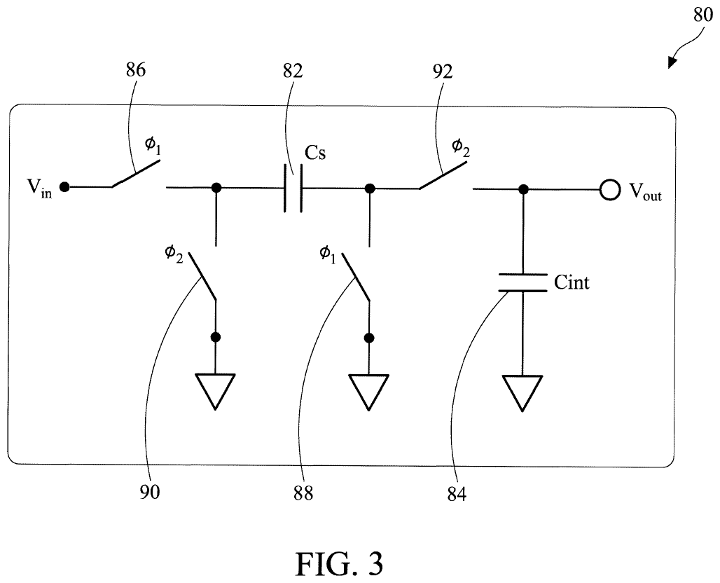

FIG. 3 is a diagram schematically illustrating an example of a passive switched-capacitor integrator 80, in accordance with some embodiments. The passive switched-capacitor integrator 80 includes a sampling capacitor Cₛ 82, an integrating capacitor Cᵢₙₜ 84, two phi1 switches 86 and 88 activated by a first clock signal φ₁ and two phi2 switches 90 and 92 activated by a second clock signal 2. The passive switched-capacitor integrator 80 has a gain factor of:

$$a = \frac{{C}_{s}}{{C}_{int} + {C}_{s}} .$$

In operation, an input signal Vᵢₙ is sampled with sampling capacitor Cₛ 82 by activating clock signal φ₁ to close the two phi1 switches 86 and 88 and by deactivating clock signal φ₂ to open the two phi2 switches 90 and 92. Next, the sampled voltage on the sampling capacitor Cₛ 82 is integrated onto the integrating capacitor Cᵢₙₜ 84 by deactivating clock signal φ₁ to open the two phi1 switches 86 and 88 and activating the clock signal φ₂ to close the two phi2 switches 90 and 92. The integrated voltage on integrating capacitor Cᵢₙₜ 84 is available at output Vout. The process is repeated to continue sampling and integrating the input signal Vᵢₙ.

In relation to the first stage 50 of FIG. 2, the passive switched-capacitor integrator 80 has a transfer function of:

$${H}_{int} ( z ) = \frac{{az}^{- 1}}{1 - ( 1 - a ) {z}^{- 1}} ,$$

and the first stage 50 has a stage output of:

$${y}_{1} = {x}_{1} + {q}_{1} \cdot {NTF}_{1} ,$$

where,

$${NTF}_{1} = \frac{g}{1 + {H}_{int}} ,$$

such that

$${y}_{1} ( z ) = {x}_{1} ( z ) + \frac{1 - ( 1 - a ) {z}^{- 1}}{1 - [ ( 1 - a ) - ag ] {z}^{- 1}} [ {q}_{1} ( z ) + {V}_{n , CMP} ( z ) ] ,$$

where V_{n,CMP} is input referred comparator noise.

For example, in some embodiments, a=0.5 and g=2, such that the output of the first stage 50 is:

$${y}_{1} ( z ) = {x}_{1} ( z ) + \frac{1 - 0.5 {z}^{- 1}}{1 + 0.5 {z}^{- 1}} [ {q}_{1} ( z ) + {v}_{n , CMP} ( z ) ] .$$

The passive switched-capacitor integrator 80 is used to implement a high-pass filter noise transfer function, for instance as indicated by the equation in paragraph above, that filters off low frequency white noise. Thus, the SAR is a noise-shaping SAR.

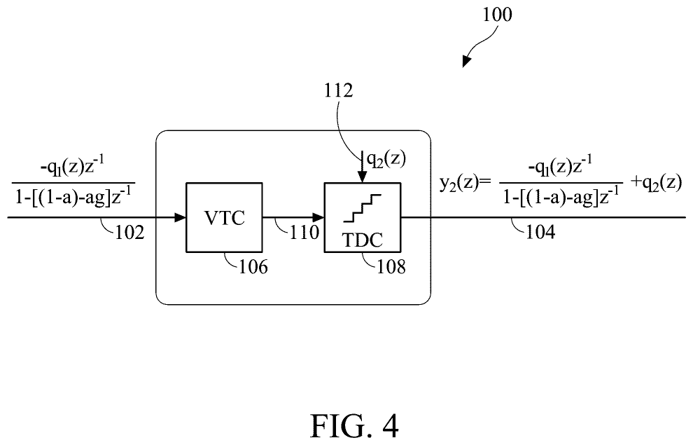

FIG. 4 is a diagram schematically illustrating a second stage 100, in accordance with some embodiments. The second stage 100 includes a time-domain quantizer that digitizes the first stage quantization error in the time domain and outputs the second digital output signal. In some embodiments, the second stage 100 is like the second stage 24 (shown in FIG. 1).

The second stage 100 includes an input 102 that receives the filtered first stage quantization error and an output 104 that transmits the second digital output signal. The second stage 100 converts the first stage quantization error into the second digital output signal that is transmitted on the output 104 to the digital filter, such as the digital filter 26 (shown in FIG. 1). The first stage quantization error, including the quantization error q₁(z) introduced by the comparator 58, is:

$$\frac{- q 1 ( z ) z - 1}{1 - [ ( 1 - a ) - ag ] {z}^{- 1}} .$$

and the output of the second stage 100 is:

$${y}_{2} ( z ) = \frac{- {q}_{1} ( z ) {z}^{- 1}}{1 - [ ( 1 - a ) - ag ] {z}^{- 1}} + {q}_{2} ( z ) ,$$

where q₂₍z) is the quantization error of the second stage 100.

The second stage 100 includes a VTC 106 that is electrically connected to a TDC 108 by conductive path 110. The VTC 106 receives the first stage quantization error at the input 102 on conductive path 78 (shown in FIG. 2) and converts it from a voltage into a corresponding time. The TDC 108 receives the corresponding time and the quantization error q₂₍z) 112 of the second stage 100 and converts the corresponding time into the second digital output signal. The TDC 108 outputs the second digital output signal on the output 104. Thus, the first stage quantization error is passively connected or coupled to the VTC 106 of the second stage 100 without the need for an active amplifier circuit. In some embodiments, the VTC 106 includes a ZCD that receives the first stage quantization error and converts the voltage into the corresponding time.

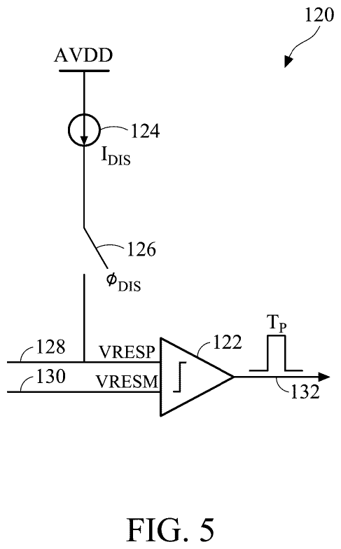

FIG. 5 is a diagram schematically illustrating a VTC 120, in accordance with some embodiments. The VTC 120 includes a ZCD 122, a discharge current source 124, and a discharge switch 126. In some embodiments, the VTC 120 is like the VTC 38 (shown in FIG. 1). In some embodiments, the VTC 120 is like the VTC 106 (shown in FIG. 4).

The ZCD 122 receives the first stage quantization error that is generated by the first stage, such as the first stage 22 (shown in FIG. 1) or the first stage 50 (shown in FIG. 2). In the present example, the ZCD 122 receives a differential signal that is a high residue voltage VRESP at a first input 128 and a low residue voltage VRESM at a second input 130.

The discharge current source 124 is electrically coupled at one end to an analog power supply voltage AVDD and at another end to one end of the discharge switch 126. Another end of the discharge switch 126 is electrically coupled to the first input 128.

In operation, the first input 128 receives the high residue voltage VRESP and the second input 130 receives the low residue voltage VRESM. The discharge switch 126 is activated by switch signal φ_{DIS} to close the discharge switch 126 and set the output 132 of the ZCD 122 to a high voltage. The discharge current source 124 provides a discharge current I_{DIS} that discharges the high residue voltage VRESP until it is equal to or less than the low residue voltage VRESM. This sets the output 132 of the ZCD 122 to a low voltage, generating a discharge pulse Tp whose width is proportional to the difference between the high residue voltage VRESP and the low residue voltage VRESM. Thus, the VTC 120 performs a voltage to time conversion.

In a system with a single residual voltage V_{RES}:

$${V}_{RES} = {V}_{IN} - {V}_{DAC ,}$$

where V_{IN} is the sampled analog input voltage and V_{DAC} is the analog output voltage of the DAC, such as the DAC 60 (shown in FIG. 2). The discharge time T_{DIS} is:

$${T}_{DIS} = ( {V}_{IN} - {V}_{DAC} + {V}_{OS} ) \cdot \frac{{C}_{T}}{{I}_{DIS}} ,$$

where Vos is an offset voltage and CT is the total capacitance on the V_{RES} node.

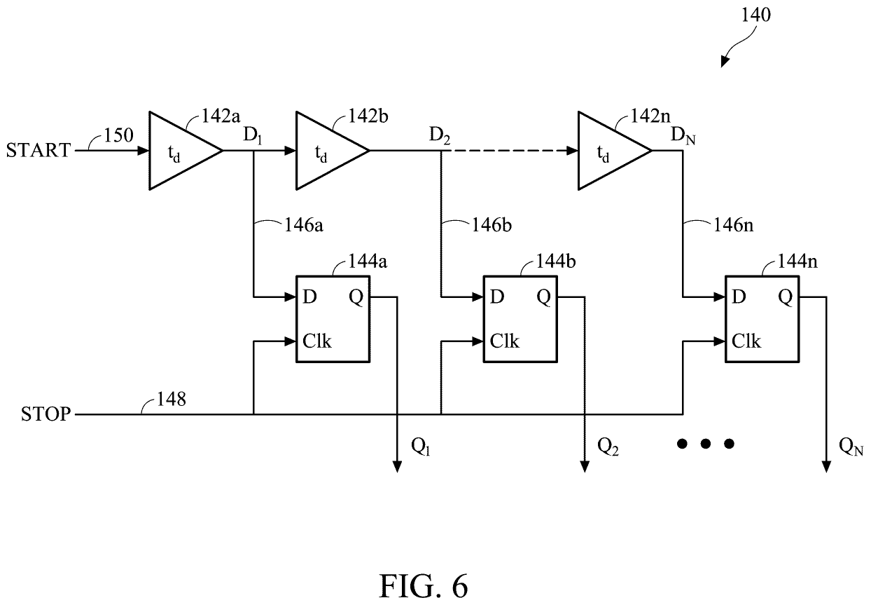

FIG. 6 is a diagram schematically illustrating a TDC 140, in accordance with some embodiments. The TDC 140 includes a digital delay line for measuring the time interval between a start event and a stop event and for generating a corresponding digital output signal that is the second digital output signal. The start event, such as the rising edge of the discharge pulse Tp of the ZCD 122 (shown in FIG. 5), is applied to the beginning of the digital delay line and the stop event, such as the falling edge of the discharge pulse Tp of the ZCD 122, latches in the status of the digital delay line. Thus, the TDC 140 converts the time interval between the start event and the stop event, such as the width of the discharge pulse Tp of the ZCD 122, into the digital output signal. In some embodiments, the TDC 140 is like the TDC 40 (shown in FIG. 1). In some embodiments, the TDC 140 is like the TDC 108 (shown in FIG. 4).

The TDC 140 includes delay cells 142a-142n and D flip-flops 144a-144n. In some embodiments, the delay cells 142a-142n are voltage-controlled delay cells. In some embodiments, one or more of the delay cells 142a-142n includes a delay locked loop (DLL) to stabilize delays of the delay cells 142a-142n against process, power supply, and temperature variations.

Each of the delay cells 142a-142n has a signal delay time ta, such that delay cell 142a outputs a delayed signal D₁ at output 146a, delay cell 142b outputs a delayed signal D₂ at output 146b, and so on, up to delay cell 142n that outputs a delayed signal DN at output 146n. The delay cells 142a-142n are electrically connected in series from delay cell 142a to delay cell 142n, such that the output 146a is connected to the input of the delay cell 142b, and so on.

Each of the D flip-flops 144a-144n includes a data input D, a clock input Clk, and an output Q. The data input D of the D flip-flop 144a is electrically coupled to the output 146a of delay cell 142a and receives the delayed signal D₁, the data input D of the D flip-flop 144b is electrically coupled to the output 146b of delay cell 142b and receives the delayed signal D₂, and so on, up to the data input D of the D flip-flop 144n is electrically coupled to the output 146n of delay cell 142n and receives the delayed signal DN. Also, each of the clock inputs Clk of the D flip-flops 144a-144n is electrically connected to a conductive path 148 that receives the stop event, such as the falling edge of the discharge pulse Tp (shown in FIG. 5).

In operation, the start event, such as the rising edge of the discharge pulse Tp of the ZCD 122, is applied to an input 150 of the delay cell 142a and propagates through one or more of the delay cells 142a-142n. The stop event, such as the falling edge of the discharge pulse Tp of the ZCD 122, latches the delayed signals D₁ to DN into the D flip-flops 144a-144n that output the latched in voltages at outputs Q₁, Q₂, to Q_{N}, respectively, for generating the corresponding digital output signal that is the second digital output signal. Thus, the TDC 140 converts the width of the discharge pulse Tp of the ZCD 122 into a digital output signal that is the second digital output signal.

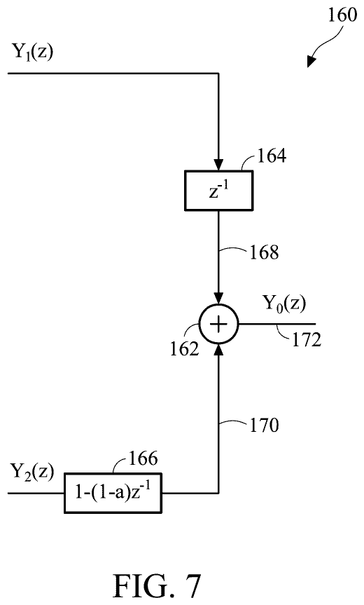

FIG. 7 is a diagram schematically illustrating a digital filter 160, in accordance with some embodiments. The digital filter 160 receives the first digital output signal Y₁(z) from the first stage and the second digital output signal Y₂(z) from the second stage and combines the signals, in the digital domain, to provide the final combined digital output signal Y₀(z). In some embodiments, the first stage is like the first stage 22 (shown in FIG. 1). In some embodiments, the first stage is like the first stage 50 (shown in FIG. 2). In some embodiments, the second stage is like the second stage 24 (shown in FIG. 1). In some embodiments, the second stage is like the second stage 100 (shown in FIG. 4). In some embodiments, the digital filter 160 is like the digital filter 26 (shown in FIG. 1).

The digital filter 160 includes an adder 162, a delay 164, and a filter function 166. The delay 164 is electrically connected to a first input 168 of the adder 162, and the filter function 166 is electrically connected to a second input 170 of the adder 162. The delay 164 receives the first digital output signal Y₁(z) and delays the first digital output signal Y₁(z) a clock period in the z-transform domain Z⁻¹. The filter function 166 receives the second digital output signal Y₂(z) and applies the function 1-(1-a)Z⁻¹ to the second digital output signal Y₂(z). The adder 162 receives the results from the delay 164 and the filter function 166 and outputs, at the output 172 of the adder 162, the final combined digital output signal Y₀(z).

In the present example, the first digital output signal Y₁(z) from the first stage is:

$${y}_{1} ( z ) = {x}_{1} ( z ) + \frac{1 - ( 1 - a ) {z}^{- 1}}{1 - [ ( 1 - a ) - ag ] {z}^{- 1}} [ {q}_{1} ( z ) + {V}_{n , CMP} ( z ) ] ,$$

and the second digital output signal Y₂(z) from the second stage is:

$${y}_{2} ( z ) = \frac{- {q}_{1} ( z ) {z}^{- 1}}{1 - [ ( 1 - a ) - ag ] {z}^{- 1}} + {q}_{2} ( z ) .$$

The final combined digital output signal Y₀(z) from the adder 162 is:

$${y}_{0} ( z ) = x ( z ) {z}^{- 1} + ( 1 - ( 1 - a ) {z}^{- 1} ) {q}_{2} ( z ) ,$$

where the quantization error q₁ introduced by the comparator 58 has been eliminated.

Also, if a=0.5 and g=2, then:

$${y}_{0} = x ( z ) {z}^{- 1} + ( 1 - 0.5 {z}^{- 1} ) {q}_{2} \cdot ( z ) .$$

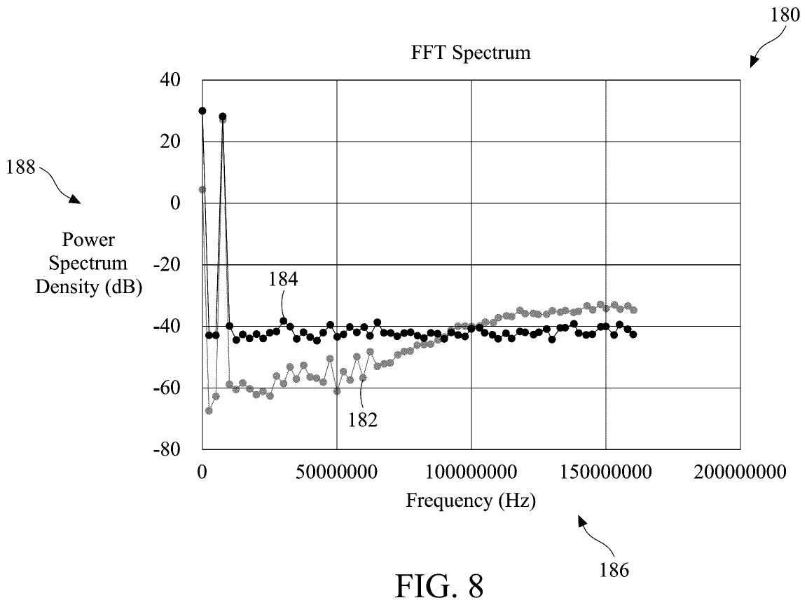

FIG. 8 is a diagram illustrating fast Fourier transform (FFT) spectrums of ADC devices 180, in accordance with some embodiments. The FFT spectrums include a simulated FFT spectrum of an ADC device that includes a noise-shaping SAR 182 and a simulated FFT spectrum of an ADC device that does not include a noise-shaping SAR 184. The ADC device that includes a noise-shaping SAR includes a passive switched-capacitor integrator that acts as a high-pass filter to filter off low frequency white noise. Thus, the ADC device that includes a noise-shaping SAR performs high-pass frequency noise shaping and digitization of quantization errors, which improves the in-band signal-to-noise ratio (SNR).

In some embodiments, the ADC device includes a first stage, a second stage, and a digital filter. In some embodiments, the ADC device is like the ADC device 20 of FIG. 1. In some embodiments the first stage is like the first stage 22, the second stage is like the second stage 24, and the digital filter is like the digital filter 26. In some embodiments, the first stage is like the first stage 50 of FIG. 2, the second stage is like the second stage 100 of FIG. 4, and the digital filter is like the digital filter 160 of FIG. 7. In some embodiments, the noise-shaping SAR is like the noise-shaping SAR 34 that includes a passive switched-capacitor integrator 36.

The FFT spectrums are graphed with frequency in hertz (Hz) along the x-axis 186 and power spectrum density in decibels (dB) along the y-axis 188. The power spectrum density of the ADC device that includes a noise-shaping SAR 182 is less than the power spectrum density of the ADC device that does not include a noise-shaping SAR 184 at frequencies less than about 90,000,000 Hz. Where, the power spectrum density of the ADC device that includes a noise-shaping SAR 182 is about −60 dB to −45 dB at frequencies less than in about 90,000,000 Hz. The power spectrum density of the ADC device that does not include a noise-shaping SAR 184 is relatively constant at −45 dB. The noise-shaping SAR includes the passive switched-capacitor integrator that acts as a high-pass filter to filter off low frequency white noise.

The ADC device that includes a noise-shaping SAR yields an improved SNR. For example, with a sampling rate of 320 mega-samples per second (MSPS), an input tone of 7.5 Mega-Hertz (MHz), a signal bandwidth of 40 MHz, and an over sampling rate (OSR) of 4 times, the ADC device that does not include a noise-shaping SAR provides a SNR of 64.5 dB and the ADC device that includes a noise-shaping SAR provides a higher SNR of 73.4 dB.

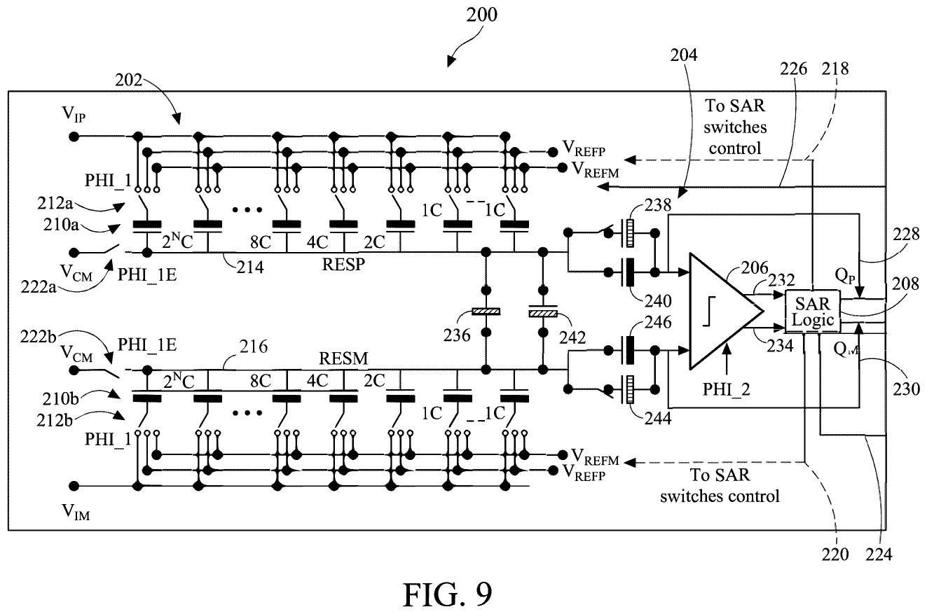

FIG. 9 is a diagram schematically illustrating a noise-shaping SAR 200 that is part of a first stage of an ADC device, in accordance with some embodiments. The noise-shaping SAR 200 includes a sample and hold circuit 202, a passive switched-capacitor integrator 204, a comparator 206, and SAR logic 208. The noise-shaping SAR 200 uses the comparator 206 to successively narrow a range that contains an input voltage. At each successive step, the noise-shaping SAR 200 compares the input voltage to an analog output of a DAC. In some embodiments, the noise-shaping SAR 200 is like the noise-shaping SAR 34 (shown in FIG. 1). In some embodiments, the passive switched-capacitor integrator 204 is like the passive switched-capacitor integrator 36 (shown in FIG. 1).

The sample and hold circuit 202 includes a set of capacitors 210a and a set of switches 212a that correspond to the differential residue voltage RESP. One side of each capacitor of the set of capacitors 210a is electrically connected to the residue voltage conductor 214 and the other side of each capacitor of the set of capacitors 210a is electrically connected to one switch of the set of switches 212a. The other side of the switches 212a are configured to be switched to an analog input voltage V_{IP}, a high reference voltage V_{REFP}, and a low reference voltage V_{REFM}. Also, the sample and hold circuit 202 includes a set of capacitors 210b and a set of switches 212b that correspond to the differential residue voltages RESM. One side of each capacitor of the set of capacitors 210b is electrically connected to the residue voltage conductor 216 and the other side of each capacitor of the set of capacitors 210b is electrically connected to one switch of the set of switches 212b. The other side of the switches 212b are configured to be switched to an analog input voltage V_{IM}, the high reference voltage V_{REFP}, and the low reference voltage V_{REFM}. In addition, the sample and hold circuit 202 includes switches 222a and 222b that connect the common mode voltage V_{CM} to the residue voltage conductors 214 and 216, respectively. Each of the sets of capacitors 210a and 210b includes a plurality of capacitors 1C and a plurality of capacitors 2C, 4C, 8C, and so on, up to 2^{N}C, where N may correspond to the number of bits to be digitized. In some embodiments, the two sets of capacitors 210a and 210b are binary weighted.

In operation, the sample and hold circuit 202 including the two sets of switches 212a and 212b receive SAR control signals from the SAR logic 208 on conductive paths 218 and 220. The control signals control the two sets of switches 212a and 212b to selectively connect the two sets of capacitors 210a and 210b to the analog input voltage V_{IP}, the analog input voltage V_{IM}, the high reference voltage V_{REFP}, and the low reference voltage V_{REFM}. Also, the control signals control the switches 222a and 222b to selectively connect the common mode voltage V_{CM} to the residue voltage conductors 214 and 216.

In some embodiments, during a first clock phase or pulse, clock signal PHI_1 is asserted to sample and hold the analog input voltage V_{IP} and the analog input voltage V_{IM}. The control signals connect the analog input voltage V_{IP} to the top plates of the capacitors 210a and the analog input voltage V_{IM} to the top plates of the capacitors 210b. At about the same time, clock signal PHI_1E is asserted to close the switches 222a and 222b and connect the bottom plates of the capacitors 210a and 210b to the common mode voltage V_{CM}. During the next clock phase or pulse, clock signal PHI_2 is asserted, such as to the comparator 206, to control a binary search algorithm that is implemented by the SAR logic 208 to generate a digital output signal that corresponds to and represents the differential analog input voltage. Next, during a third clock phase or pulse, a clock signal PHI_3 (not shown) is asserted to activate the second stage of the ADC device to digitize the first stage quantization error and output the second digital output signal. The SAR logic 208 is electrically connected to the second stage by conductive path 224 to control outputting the second digital output signal. Also, the noise-shaping SAR 200 is electrically connected to the second stage by conductive path 226 to receive signals from the second stage.

The passive switched-capacitor integrator 204 functions as a high-pass loop filter to filter off low frequency white noise during operation of the noise-shaping SAR 200. The passive switched-capacitor integrator 204 integrates the differential residue voltage RESP and the differential residue voltage RESM, which are based on comparisons of the analog signals from the noise-shaping SAR 200 to the analog input voltage V_{IP} and the analog input voltage V_{IM}. Based on the differential residue voltage RESP and the differential residue voltage RESM, the passive switched-capacitor integrator 200 generates a first stage quantization error that is transmitted to the second stage. The passive switched-capacitor integrator 200 includes multiple sampling capacitors that alternately sample the residual signals and integrate the sampled signals onto an integrator capacitor, such that throughput, i.e., the sample rate, of the ADC device is not reduced.

The sample and hold circuit 202 is electrically coupled to the passive switched-capacitor integrator 204 by residue voltage conductors 214 and 216. The passive switched-capacitor integrator 204 is electrically coupled to the comparator 206 and to the second stage by differential input paths 228 and 230. The comparator 206 is electrically coupled to the SAR logic 208 by differential output paths 232 and 234, and the SAR logic 208 is electrically coupled to the second stage by differential input paths 228 and 230.

The passive switched-capacitor integrator 204 includes 6 capacitors including capacitor C_{RP1} 236, capacitor C_{RP2} 238, capacitor C_{INTP} 240, capacitor C_{RM1} 242, capacitor C_{RM2} 244, and capacitor C_{INTM} 246. Capacitor C_{RP1} 236, capacitor C_{RP2} 238, and capacitor C_{INTP} 240 are for sampling and integrating the differential residue voltage RESP. Capacitor C_{RM1} 242, capacitor C_{RM2} 244, and capacitor C_{INTM} 246 are for sampling and integrating the differential residue voltage RESM.

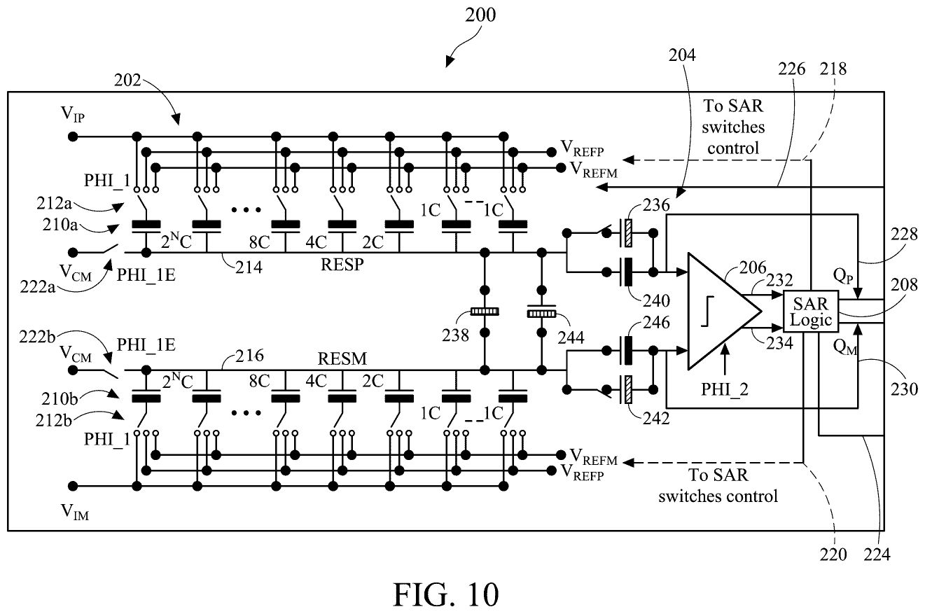

As shown in FIG. 9, during one set of clock signals PHI_1, PHI_2, and PHI_3, capacitor C_{RP1} 236 samples the differential residue voltage RESP and capacitor C_{RM1} 242 samples the differential residue voltage RESM. At the same time, capacitor C_{RP2} 238 integrates a previously obtained sample of the differential residue voltage RESP onto capacitor C_{INTP} 240, and capacitor C_{RM2} 244 integrates a previously obtained sample of the differential residue voltage RESM onto capacitor C_{INTM} 246. This arrangement of the capacitors including capacitor C_{RP1} 236, capacitor C_{RP2} 238, capacitor C_{INTP} 240, capacitor C_{RM1} 242, capacitor C_{RM2} 244, and capacitor C_{INTM} 246 is changed or switched to another arrangement of the capacitors during the next set of clock signals PHI_1, PHI_2, and PHI_3, as shown in FIG. 10.

FIG. 10 is a diagram schematically illustrating the noise-shaping SAR 200 with the passive switched-capacitor integrator 204 having the 6 capacitors including capacitor C_{RP1} 236, capacitor C_{RP2} 238, capacitor C_{INTP} 240, capacitor C_{RM1} 242, capacitor C_{RM2} 244, and capacitor C_{INTM} 246 switched to another arrangement for the next set of clock signals PHI_1, PHI_2, and PHI_3, in accordance with some embodiments. The other elements of the noise-shaping SAR 200 are like the noise-shaping SAR 200 in FIG. 9, such that the description will not be repeated here.

As shown in FIG. 10, during the next set of clock signals PHI_1, PHI_2, and PHI_3, capacitor C_{RP2} 238 samples the differential residue voltage RESP and capacitor C_{RM2} 244 samples the differential residue voltage RESM. At the same time, capacitor C_{RP1} 236 integrates the previously obtained sample of the differential residue voltage RESP onto capacitor C_{INTP} 240, and capacitor C_{RM1} 242 integrates the previously obtained sample of the differential residue voltage RESM onto capacitor C_{INTM} 246.

Thus, during one set of clock signals PHI_1, PHI_2, and PHI_3, the sampling and integrating capacitors are set up in one arrangement and during the next set of clock signals PHI_1, PHI_2, and PHI_3, the sampling and integrating capacitors are set up in the other arrangement, and the alternating process repeats.

The sampling by one capacitor, such as capacitor C_{RP1} 236, is completed while integrating the sample from the other capacitor, such as capacitor C_{RP2} 238, and so on. Alternating capacitors, back and forth, from sampling during one set of clock signals PJI_1, PHI_2, and PHI_3 to integrating during the next set of clock signals PHI_1, PHI_2, and PHI 3. This saves time, as there is no need for additional clock cycles for sampling and integrating the differential residue voltage RESP and the differential residue voltage RESM between sets of clock signals PHI_1, PHI_2, and PHI_3. Also, throughput, i.e., the sample rate, of the ADC device is not reduced.

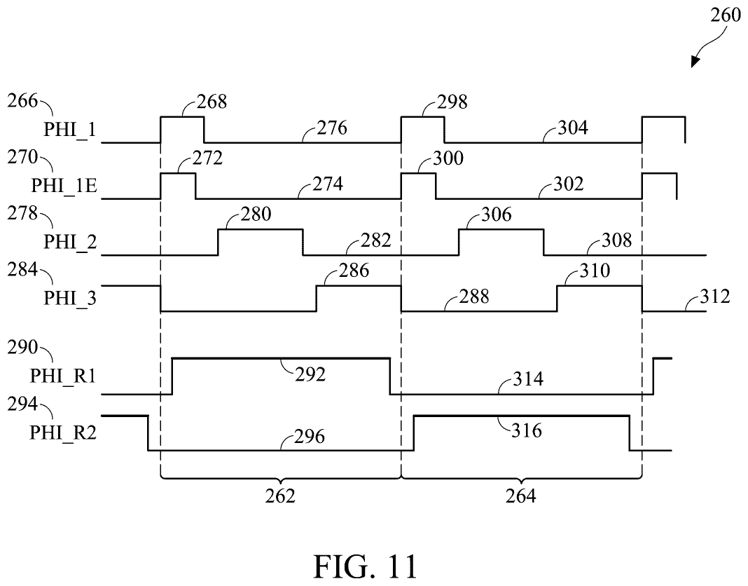

FIG. 11 is a timing diagram 260 illustrating the operation of the noise-shaping SAR 200 with the passive switched-capacitor integrator 204, in accordance with some embodiments. The timing diagram 260 includes a first set of clock signals 262 and a second set of clock signals 264 that alternate during the analog to digital conversion process.

During the first set of clock signals 262, clock signal PHI_1 266 rises to a high voltage level 268 to sample and hold the analog input voltage V_{IP} and the analog input voltage V_{IM}. The high voltage level 268 of clock signal PHI_1 266 connects the analog input voltage V_{IP} to the top plates of the capacitors 210a and the analog input voltage V_{IM} to the top plates of the capacitors 210b. Also, the clock signal PHI_1E 270 rises to a high voltage level 272 to close the switches 222a and 222b and connect the bottom plates of the capacitors 210a and 210b to the common mode voltage V_{CM}. The clock signal PHI_1E 268 returns to a low voltage level 274 and shortly thereafter the clock signal PHI_1 266 returns to a low voltage level 276.

After the clock signal PHI_1 266 returns to the low voltage level 276, the clock signal PHI_2 278 rises to a high voltage level 280 and the binary search algorithm is implemented by the SAR logic 208 to generate a first digital output signal that corresponds to the analog input voltage V_{IP} and the analog input voltage V_{IM}. The clock signal PHI_2 278 then returns to a low voltage level 282.

After the clock signal PHI_2 278 returns to the low voltage level 282, the clock signal PHI_3 284 rises to a high voltage level 286 to activate the second stage of the ADC device. The second stage receives and digitizes the first stage quantization error and outputs the second digital output signal. The clock signal PHI_3 284 returns to a low voltage level 288 at the end of the first set of clock signals 262.

During the first set of clock signals 262, the clock signal PHI_R1 290 rises to a high voltage level 292 and the clock signal PHI_R2 294 is at a low voltage level 296, which connects the capacitor C_{RP1} 236 to sample the differential residue voltage RESP and the capacitor C_{RM1} 242 to sample the differential residue voltage RESM, and connects the capacitor C_{RP2} 238 to integrate a previously obtained sample of the differential residue voltage RESP onto the capacitor C_{INTP} 240, and the capacitor C_{RM2} 244 to integrate a previously obtained sample of the differential residue voltage RESM onto the capacitor C_{INTM} 246. This setting or arrangement of the capacitors including capacitor C_{RP1} 236, capacitor C_{RP2} 238, capacitor C_{INTP} 240, capacitor C_{RM1} 242, capacitor C_{RM2} 244, and capacitor C_{INTM} 246 is changed to another setting or arrangement during the second set of clock signals 264.

During the second set of clock signals 264, the clock signals PHI_1 266, PHI_1E 270, PHI_2 278, and PHI_3 284 are like they are during the first set of clock signals 262. The clock signal PHI_1 266 rises to a high voltage level 298 to sample and hold the analog input voltage V_{IP} and the analog input voltage V_{IM}. The high voltage level 298 of clock signal PHI_1 266 connects the analog input voltage V_{IP} to the top plates of the capacitors 210a and the analog input voltage V_{IM} to the top plates of the capacitors 210b. Also, the clock signal PHI_1E 270 rises to a high voltage level 300 to close the switches 222a and 222b and connect the bottom plates of the capacitors 210a and 210b to the common mode voltage V_{CM}. The clock signal PHI_1E 270 returns to a low voltage level 302 and shortly thereafter the clock signal PHI_1 266 returns to a low voltage level 304.

After the clock signal PHI_1 266 returns to the low voltage level 304, the clock signal PHI_2 278 rises to a high voltage level 306 and the binary search algorithm is implemented by the SAR logic 208 to generate a first digital output signal that corresponds to the analog input voltage V_{IP} and the analog input voltage V_{IM}. The clock signal PHI_2 278 then returns to a low voltage level 308.

After the clock signal PHI_2 278 returns to the low voltage level 308, the clock signal PHI_3 284 rises to a high voltage level 310 to activate the second stage of the ADC device. The second stage receives and digitizes the first stage quantization error and outputs the second digital output signal. The clock signal PHI_3 284 returns to a low voltage level 312 at the end of the second set of clock signals 264.

During the second set of clock signals 264, the clock signal PHI_R1 290 is at a low voltage level 314 and the clock signal PHI_R2 294 rises to a high voltage level 316, which connects the capacitor C_{RP2} 238 to sample the differential residue voltage RESP and connects the capacitor C_{RM2} 244 to sample the differential residue voltage RESM, and connects the capacitor C_{RP1} 236 to integrate the previously obtained sample of the differential residue voltage RESP onto the capacitor C_{INTP} 240, and connects the capacitor C_{RM1} 242 to integrate the previously obtained sample of the differential residue voltage RESM onto the capacitor C_{INTM} 246.

Thus, during the first set of clock signals 262, the sampling and integrating capacitors are connected in one arrangement, and during the second set of clock signals 264, the sampling and integrating capacitors are connected in another arrangement. These two arrangements alternate from one to the other during the analog to digital conversion process. Alternating the capacitor arrangements saves time, as there is no need for additional clock cycles between the first and second sets of clock signals 262 and 264 for sampling and integrating the differential residue voltage RESP and the differential residue voltage RESM. Also, throughput, i.e., the sample rate, of the ADC device is increased or at least not reduced.

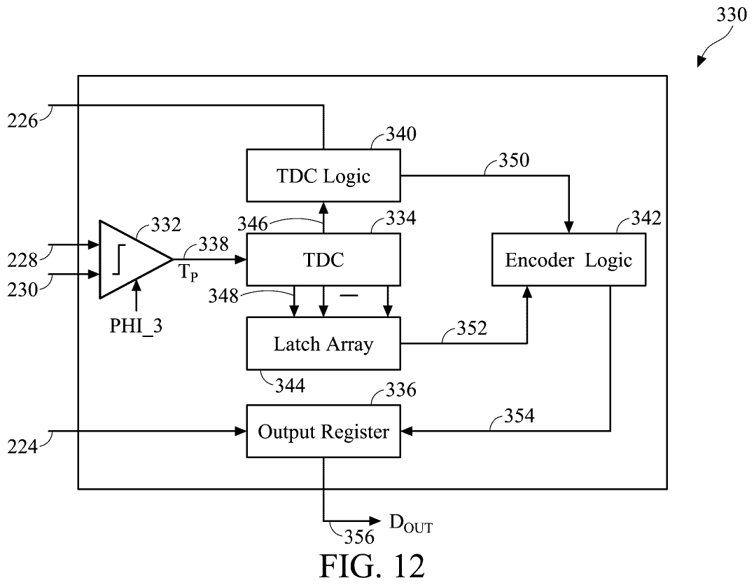

FIG. 12 is a diagram schematically illustrating a second stage 330, in accordance with some embodiments. The second stage 330 receives the first stage quantization error and converts the first stage quantization error to a second digital output signal that is transmitted to a digital filter, such as the digital filter 26 (shown in FIG. 1). In some embodiments, the second stage 330 is like the second stage 24 (shown in FIG. 1). In some embodiments, the second stage 330 is like the second stage 100 of FIG. 4.

The second stage 330 is electrically coupled to the noise-shaping SAR 200 of FIGS. 9 and 10. The second stage 330 is electrically coupled to the comparator 206 and the SAR logic 208 by differential input paths 228 and 230. Also, the second stage 330 is electrically coupled to the SAR logic 208 by conductive path 224 and, in some embodiments, the second stage 330 is electrically coupled to the noise-shaping SAR 200 by conductive path 226 for operation of the noise-shaping SAR 200.

The second stage 330 receives and digitizes the filtered first stage quantization error and outputs the second digital output signal. The second stage 330 is activated when the clock signal PHI_3 284 (shown in FIG. 11) is at the high voltage level 286 and 310. The clock signal PHI_3 284 returns to the low voltage level 288 and 312 at the end of each set of clock signals.

The second stage 330 includes a ZCD 332, a TDC 334, and an output register 336. The ZCD 332 is electrically coupled to the differential inputs of the comparator 206 and to the SAR logic 208 by the differential input paths 228 and 230. Also, the ZCD 332 is electrically coupled to the TDC 334 by conductive path 338. The SAR logic 208 is electrically coupled to the output register 336 by conductive path 224 to control operation of the output register 336. In some embodiments, the ZCD 332 is like the ZCD 122 (shown in FIG. 5). In some embodiments, the ZCD 332 is part of the VTC 120 of FIG. 5, which includes the ZCD 122, the discharge current source 124, and the discharge switch 126.

The ZCD 332 receives a differential input signal that is the first stage filtered quantization error through the differential input paths 228 and 230. The differential input signal includes a high residue voltage and a low residue voltage. The ZCD 332 performs a voltage-to-time on the differential input signal and outputs a pulse Tp whose width is proportional to the difference between the high residue voltage and the low residue voltage. In some embodiments, the ZCD 332 is part of the VTC 120 of FIG. 5, such that the ZCD 332 functions as described in relation to the VTC 120 of FIG. 5.

The TDC 334 receives the pulse Tp and converts the pulse Tp into the second digital output signal. In some embodiments, the TDC 334 is like the TDC 140 of FIG. 6. In some embodiments, the TDC 334 is like the TDC 40 (shown in FIG. 1).

In some embodiments, the second stage 330 further includes a TDC logic 340, an encoder logic 342, and a latch array 344. The TDC 334 is electrically coupled to the TDC logic 340 by conductive path 346, and to the latch array 344 by conductive paths 348. The TDC logic 340 is electrically coupled to the encoder logic 342 by conductive path 350, and the TDC logic 340 is electrically coupled to the noise-shaping SAR 200 by conductive path 226 to provide signals for operation of the noise-shaping SAR 200. The latch array 344 is electrically coupled to the encoder logic 342 by conductive path 352, and the encoder logic 342 is electrically coupled to the output register 336 by conductive path 354.

In operation, the TDC 334 receives the pulse Tp and outputs signals to the TDC logic 340 and the latch array 344, which output signals to the encoder logic 342. The encoder logic 342, encodes the received signals and outputs the second digital output signal to the output register 336 that outputs the second digital output signal on output path D_{OUT} 356.

Thus, the second stage 330 receives the first stage quantization error and converts the first stage quantization error to the second digital output signal that is transmitted on the output path D_{OUT} to the digital filter, such as the digital filter 26. The digital filter receives the first digital output signal from the first stage and the second digital output signal from the second stage and combines the first digital output signal and the second digital output signal to provide the final combined digital output signal at the output of the digital filter.

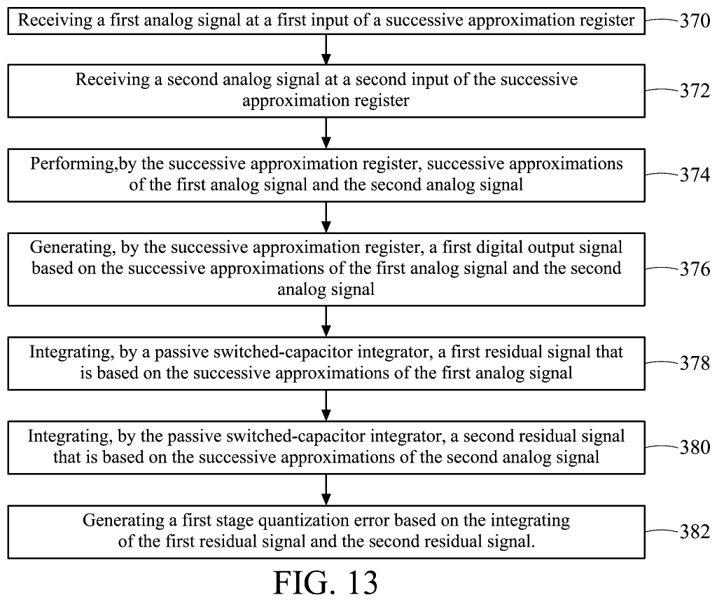

FIG. 13 is a diagram illustrating a method of converting an analog signal to a digital signal in an ADC device, in accordance with some embodiments. The ADC device includes a noise-shaping SAR that includes a passive switched-capacitor integrator. In some embodiments, the ADC device is like the ADC device 20 of FIG. 1. In some embodiments, the noise-shaping SAR is like the noise-shaping SAR 34 (shown in FIG. 1). In some embodiments the noise-shaping SAR is like the noise-shaping SAR 200 (shown in FIGS. 9 and 10). In some embodiments, the passive switched-capacitor integrator is like the passive switched-capacitor integrator 36 (shown in FIG. 1). In some embodiments, the passive switched-capacitor integrator is like the passive switched-capacitor integrator 204 (shown in FIGS. 9 and 10).

At 370, the method includes receiving a first analog signal at a first input of a SAR and, at 372, the method includes receiving a second analog signal at a second input of the SAR. At 374, the method includes performing, by the SAR, successive approximations of the first analog signal and the second analog signal and, at 376, the method includes generating, by the SAR, a first digital output signal based on the successive approximations of the first analog signal and the second analog signal.

At 378, the method includes integrating, by a passive switched-capacitor integrator, a first residual signal that is based on the successive approximations of the first analog signal. In some embodiments, integrating the first residual signal includes sampling the first residual signal by a first sampling capacitor during a first set of signals and providing a first sample of the first residual signal to a first integrator capacitor during a second set of signals that is different than the first set of signals and alternates with the first set of signals, and sampling the first residual signal by a second sampling capacitor during the second set of signals and providing a second sample of the first residual signal to the first integrator capacitor during the first set of signals.

At 380, the method includes integrating, by the passive switched-capacitor integrator, a second residual signal that is based on the successive approximations of the second analog signal. In some embodiments, integrating the second residual signal includes sampling the second residual signal by a third sampling capacitor during the first set of signals and providing a first sample of the second residual signal to a second integrator capacitor during the second set of signals, and sampling the second residual signal by a fourth sampling capacitor during the second set of signals and providing a second sample of the second residual signal to the second integrator capacitor during the first set of signals.

At 382, the method includes generating a first stage quantization error based on the integrating of the first residual signal and the second residual signal.

In some embodiments, the method includes, during each of the first set of signals and the second set of signals, sampling and holding, by the SAR, the first analog signal and the second analog signal during a first time, performing successive approximations of the first analog signal and the second analog signal during a second time, and converting the first stage quantization error from a voltage to a corresponding time and triggering conversion from the corresponding time to the second digital output signal during a third time. In some embodiments, the method includes receiving the first stage quantization error at a second stage, converting the first stage quantization error to a second digital output signal, and combining the first digital output signal and the second digital output signal to provide a combined digital output signal.

Disclosed embodiments thus provide an ADC device that includes a noise-shaping SAR with a passive switched-capacitor integrator. A first stage includes the noise-shaping SAR that performs successive approximations of analog input signals to provide a first digital output signal. The noise-shaping SAR with the passive switched-capacitor integrator acts as a high-pass filter to filter off low frequency white noise. The passive switched-capacitor integrator integrates residue signals and generates a first stage quantization error. A second stage converts the first stage quantization error to a second digital output signal, and a digital filter combines the first digital output signal and the second digital output signal to provide a combined final digital output signal.

Disclosed embodiments further provide an ADC device that includes a passive switched-capacitor integrator that includes a first sampling capacitor configured to sample a first residue signal during a first set of signals and provide a first sample of the first residue signal to a first integrator capacitor during a second set of signals that is different than the first set of signals and alternates with the first set of signals, a second sampling capacitor configured to sample the first residue signal during the second set of signals and provide a second sample of the first residue signal to the first integrator capacitor during the first set of signals, a third sampling capacitor configured to sample a second residue signal during the first set of signals and provide a first sample of the second residue signal to a second integrator capacitor during the second set of signals, and a fourth sampling capacitor configured to sample the second residue signal during the second set of signals and provide a second sample of the second residue signal to the second integrator capacitor during the first set of signals.

Further disclosed embodiments include a method of converting an analog signal to a digital signal in an ADC device. The method includes: performing, by a SAR, successive approximations of a first analog signal and a second analog signal; generating, by the SAR, a first digital output signal based on the successive approximations of the first analog signal and the second analog signal; integrating, by a passive switched-capacitor integrator, a first residue signal that is based on the successive approximations of the first analog signal; integrating, by the passive switched-capacitor integrator, a second residue signal that is based on the successive approximations of the second analog signal; and generating a first stage quantization error based on the integrating of the first residual signal and the second residual signal.

Advantages of the disclosed embodiments include scalability benefits in deep nanoscale processes, being implemented in low power supply voltage applications, and being used in analog circuits without resorting to IO devices that have higher voltage ratings.

In accordance with some embodiments, an ADC device includes a first stage, a second stage, and a digital filter. The first stage has a first input that receives a first analog input signal and an output that transmits a first digital output signal that is based on the first analog input signal. The first stage includes a SAR that receives the first analog input signal and performs successive approximations of the first analog input signal to provide the first digital output signal. The SAR includes a passive switched-capacitor integrator that filters off low frequency white noise and integrates a first residual signal that is based on comparisons of the successive approximations of the first analog input signal to the first analog input signal to generate a first stage quantization error. The second stage receives the first stage quantization error and converts the first stage quantization error to a second digital output signal. The digital filter combines the first digital output signal and the second digital output signal to provide a combined digital output signal.

In accordance with further embodiments, an analog-to-digital converter device includes a first stage having a first input that receives a first analog signal, a second input that receives a second analog signal, and an output that transmits a first digital output signal based on the first analog signal and the second analog signal. The first stage includes a successive approximation register that performs successive approximations of the first analog signal and the second analog signal to provide the first digital output signal. The successive approximation register includes a passive switched-capacitor integrator that integrates a first residual signal that is based on the successive approximations of the first analog signal and a second residual signal that is based on the successive approximations of the second analog signal to provide a first stage quantization error. The passive switched-capacitor integrator includes a first sampling capacitor configured to sample the first residual signal during a first set of signals and provide a first sample of the first residual signal to a first integrator capacitor during a second set of signals that is different than the first set of signals and alternates with the first set of signals, a second sampling capacitor configured to sample the first residual signal during the second set of signals and provide a second sample of the first residual signal to the first integrator capacitor during the first set of signals, a third sampling capacitor configured to sample the second residual signal during the first set of signals and provide a first sample of the second residual signal to a second integrator capacitor during the second set of signals, and a fourth sampling capacitor configured to sample the second residual signal during the second set of signals and provide a second sample of the second residual signal to the second integrator capacitor during the first set of signals.

In accordance with still further disclosed aspects, a method of converting an analog signal to a digital signal in an analog-to-digital converter device includes: receiving a first analog signal at a first input of a SAR; receiving a second analog signal at a second input of the SAR; performing, by the SAR, successive approximations of the first analog signal and the second analog signal; generating, by the SAR, a first digital output signal based on the successive approximations of the first analog signal and the second analog signal; integrating, by a passive switched-capacitor integrator, a first residual signal that is based on the successive approximations of the first analog signal; integrating, by the passive switched-capacitor integrator, a second residual signal that is based on the successive approximations of the second analog signal; and generating a first stage quantization error based on the integrating of the first residual signal and the second residual signal.

This disclosure outlines various embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. An analog-to-digital converter device, comprising:
a first stage having a first input that receives a first analog input signal and an output that transmits a first digital output signal that is based on the first analog input signal, the first stage includes a successive approximation register that receives the first analog input signal and performs successive approximations of the first analog input signal to provide the first digital output signal, the successive approximation register includes a passive switched-capacitor integrator that filters off low frequency white noise and integrates a first residual signal that is based on comparisons of the successive approximations of the first analog input signal to the first analog input signal to generate a first stage quantization error;
a second stage receives the first stage quantization error and converts the first stage quantization error to a second digital output signal; and
a digital filter combines the first digital output signal and the second digital output signal to provide a combined digital output signal.

2. The device of claim 1, wherein the successive approximation register generates an analog signal that is based on the successive approximations controlled by the successive approximation register and compares the analog signal to the first analog input signal to generate the first residual signal.

3. The device of claim 1, wherein the first stage includes a second input that receives a second analog input signal and the successive approximation register samples and holds the first analog input signal and the second analog input signal.

4. The device of claim 1, wherein the passive switched-capacitor integrator includes a first sampling capacitor configured to sample the first residual signal during a first set of signals and provide a first sample of the first residual signal to a first integrator capacitor during a second set of signals that is different than the first set of signals and alternates with the first set of signals, and a second sampling capacitor configured to sample the first residual signal during the second set of signals and provide a second sample of the first residual signal to the first integrator capacitor during the first set of signals.

5. The device of claim 4, wherein the passive switched-capacitor integrator includes a third sampling capacitor configured to sample a second residual signal during the first set of signals and provide a first sample of the second residual signal to a second integrator capacitor during the second set of signals and a fourth sampling capacitor configured to sample the second residual signal during the second set of signals and provide a second sample of the second residual signal to the second integrator capacitor during the first set of signals.

6. The device of claim 5, wherein the second stage receives an integrated first residual voltage from the first integrator capacitor and an integrated second residual voltage from the second integrator capacitor.

7. The device of claim 5, wherein the second stage includes a voltage-to-time converter that receives an integrated first residual voltage from the first integrator capacitor and an integrated second residual voltage from the second integrator capacitor.

8. The device of claim 7, wherein the voltage-to-time converter includes a zero-crossing detector that receives the integrated first residual voltage from the first integrator capacitor and the integrated second residual voltage from the second integrator capacitor.

9. The device of claim 7, wherein the second stage includes a time-to-digital converter connected to the voltage-to-time converter and configured to provide the second digital output signal.

10. The device of claim 4, wherein, during each of the first set of signals and the second set of signals, the first stage samples and holds the first analog input signal during a first pulse, performs successive approximations of the first analog input signal during a second pulse, and converts the first stage quantization error from a voltage to a corresponding time and triggers conversion from the corresponding time to the second digital output signal during a third pulse.

11. An analog-to-digital converter device, comprising:
a first stage having a first input that receives a first analog signal, a second input that receives a second analog signal, and an output that transmits a first digital output signal based on the first analog signal and the second analog signal, the first stage includes a successive approximation register that performs successive approximations of the first analog signal and the second analog signal to provide the first digital output signal, the successive approximation register includes a passive switched-capacitor integrator that integrates a first residual signal that is based on the successive approximations of the first analog signal and a second residual signal that is based on the successive approximations of the second analog signal to provide a first stage quantization error,
wherein the passive switched-capacitor integrator includes a first sampling capacitor configured to sample the first residual signal during a first set of signals and provide a first sample of the first residual signal to a first integrator capacitor during a second set of signals that is different than the first set of signals and alternates with the first set of signals, a second sampling capacitor configured to sample the first residual signal during the second set of signals and provide a second sample of the first residual signal to the first integrator capacitor during the first set of signals, a third sampling capacitor configured to sample the second residual signal during the first set of signals and provide a first sample of the second residual signal to a second integrator capacitor during the second set of signals, and a fourth sampling capacitor configured to sample the second residual signal during the second set of signals and provide a second sample of the second residual signal to the second integrator capacitor during the first set of signals.

12. The device of claim 11, wherein, during each of the first set of signals and the second set of signals, the successive approximation register is configured to sample and hold the first analog signal and the second analog signal during a first pulse, perform successive approximations of the first analog signal and the second analog signal during a second pulse, and convert the first stage quantization error from a voltage to a corresponding time and trigger conversion from the corresponding time to the second digital output signal during a third pulse.

13. The device of claim 11, comprising:
a second stage that receives the first stage quantization error and converts the first stage quantization error to a second digital output signal; and
a digital filter that combines the first digital output signal and the second digital output signal to provide a combined digital output signal.

14. The device of claim 13, wherein the second stage includes a voltage-to-time converter connected to a time-to-digital converter, wherein the voltage-to-time converter includes a zero-crossing detector that receives an integrated first residual voltage from the first integrator capacitor and an integrated second residual voltage from the second integrator capacitor, and the time-to-digital converter generates the second digital output signal.

15. The device of claim 13, wherein the digital filter reduces or eliminates the first stage quantization error.

16. A method of converting an analog signal to a digital signal in an analog-to-digital converter device, the method comprising:
receiving a first analog signal at a first input of a successive approximation register;
receiving a second analog signal at a second input of the successive approximation register;
performing, by the successive approximation register, successive approximations of the first analog signal and the second analog signal;
generating, by the successive approximation register, a first digital output signal based on the successive approximations of the first analog signal and the second analog signal;
integrating, by a passive switched-capacitor integrator, a first residual signal that is based on the successive approximations of the first analog signal;
integrating, by the passive switched-capacitor integrator, a second residual signal that is based on the successive approximations of the second analog signal; and
generating a filtered first stage quantization error based on the integrating of the first residual signal and the second residual signal.

17. The method of claim 16, wherein integrating the first residual signal includes:
sampling the first residual signal by a first sampling capacitor during a first set of signals and providing a first sample of the first residual signal to a first integrator capacitor during a second set of signals that is different than the first set of signals and alternates with the first set of signals; and
sampling the first residual signal by a second sampling capacitor during the second set of signals and providing a second sample of the first residual signal to the first integrator capacitor during the first set of signals.

18. The method of claim 17, wherein integrating the second residual signal includes:
sampling the second residual signal by a third sampling capacitor during the first set of signals and providing a first sample of the second residual signal to a second integrator capacitor during the second set of signals; and
sampling the second residual signal by a fourth sampling capacitor during the second set of signals and providing a second sample of the second residual signal to the second integrator capacitor during the first set of signals.

19. The method of claim 18, comprising, during each of the first set of signals and the second set of signals:
sampling and holding, by the successive approximation register, the first analog signal and the second analog signal during a first time;
performing successive approximations of the first analog signal and the second analog signal during a second time; and
converting the filtered first stage quantization error from a voltage to a corresponding time and triggering conversion from the corresponding time to a second digital output signal during a third time.

20. The method of claim 16, comprising:
receiving the filtered first stage quantization error at a second stage;
converting the filtered first stage quantization error to a second digital output signal; and
combining the first digital output signal and the second digital output signal to provide a combined digital output signal.
